(19) United States
(12) Patent Application Publication
(10) Pub. No.: US 2026/0076208 A1
(43) Pub. Date: Mar. 12, 2026

(54) MANUFACTURING METHOD OF ELECTROMAGNETIC SHIELDING STRUCTURE AND PACKAGING STRUCTURE

(71) Applicant: Forehope Electronic (Ningbo) Co., Ltd., Ningbo City (CN)

(72) Inventors: Lei ZHONG, Ningbo City (CN); Yupeng XU, Ningbo City (CN); Li Li, Ningbo City (CN); Zhenghong HE, Ningbo City (CN)

(21) Appl. No.: 19/184,490

(22) Filed: Apr. 21, 2025

(30) Foreign Application Priority Data
Sep. 9, 2024 (CN) 2024112527758

(51) Int. Cl. H01L 23/552; H01L 21/56; H01L 23/00

(52) U.S. Cl. CPC H10W 42/20; H10W 74/016; H10W 72/0198; H10W 74/10; H10W 90/724

(57) ABSTRACT

Provided are manufacturing method of electromagnetic shielding structure and packaging structure. Manufacturing method includes providing substrate having first element; and forming shielding portion on substrate by using 3D printing technology, wherein shielding portion is arranged at periphery of first element; and the step includes: constructing three-dimensional model of shielding portion; identifying target position on substrate; and laying printing material at target position based on three-dimensional model to pre-form shielding portion; injecting molding compound onto substrate to form encapsulation that encapsulates first element and shielding portion, wherein molding compound undergoes crosslinking reaction with printing material; grinding encapsulation so that shielding portion is exposed from surface of encapsulation; and forming metal layer on surface of encapsulation, wherein metal layer is electrically connected to shielding portion, and at least one of metal layer and shielding portion has grounding properties.

### CROSS-REFERENCE TO RELATED APPLICATIONS

The present disclosure claims the priority to the Chinese patent application with the filling No. 2024112527758 filed with the Chinese Patent Office on Sep. 9, 2024, and entitled “MANUFACTURING METHOD OF ELECTROMAGNETIC SHIELDING STRUCTURE AND PACKAGING STRUCTURE”, the contents of which are incorporated herein by reference in entirety.

### TECHNICAL FIELD

The present disclosure relates to the technical field of semiconductor packaging, and specifically to a manufacturing method of an electromagnetic shielding structure and a packaging structure.

### BACKGROUND ART

With the rapid development of the semiconductor industry, system-level packaging module structures are widely applied in the semiconductor industry. After packaging chips with different functions, stacking is performed. The main advantages include high-density integration, small packaging product size, good product performance, and fast signal transmission frequency. As electronic products are applied to the communication field with high-frequency signals, products are thus required to be provided with a partitioned electromagnetic shielding structure to prevent the electromagnetic interference generated by various chips and components from affecting each other. The existing partitioned shielding technology mainly adopts wire bonding to form a cage-shaped shielding structure.

The cage-shaped shielding structure is to arrange wiring in the substrate and form grounding pads on the surface of the substrate, where the grounding pads are arranged around the chips or components that require shielding, and vertical metal wires are bonded onto the grounding pads. The vertical metal wires surround the chips or components that require shielding, thereby forming the cage-shaped shielding structure.

Since the existing machine platform for bonding vertical metal wires adopts metal bonding wire for wire bonding, the long diameter of the vertical metal wires is relatively large. Under the impact of the subsequent molding flow of encapsulation, deformation or breakage easily occurs, leading to uneven spacing between adjacent vertical metal wires, which is prone to causing spurious signals to pass through and reducing the shielding effect. In addition, the existing vertical metal wires have a large difference in the coefficient of thermal expansion compared to the encapsulation, making structural delamination likely to occur.

### SUMMARY

A manufacturing method of an electromagnetic shielding structure is provided, including:
providing a substrate having a first element;
forming a shielding portion on the substrate by using 3D printing technology, wherein the shielding portion is arranged at a periphery of the first element; and the step comprises: constructing a three-dimensional model of the shielding portion; identifying a target position on the substrate; and laying printing material at the target position in accordance with the three-dimensional model to pre-form the shielding portion;
injecting a molding compound onto the substrate to form an encapsulation that encapsulates the first element and the shielding portion, wherein the molding compound undergoes a crosslinking reaction with the printing material;
grinding the encapsulation so that the shielding portion is exposed from a surface of the encapsulation; and
forming a metal layer on the surface of the encapsulation, wherein the metal layer is electrically connected to the shielding portion, and at least one of the metal layers and the shielding portion has grounding properties.

A packaging structure is prepared by adopting the manufacturing method of the electromagnetic shielding structure according to any one of the foregoing embodiments.

### BRIEF DESCRIPTION OF DRAWINGS

In order to more clearly illustrate the technical solutions of the embodiments of the present disclosure, the following will briefly introduce the drawings used in the embodiments. It should be understood that the following drawings only show some embodiments of the present disclosure, and therefore it should not be regarded as a limitation on the scope. Those ordinary skilled in the art can also obtain other related drawings based on these drawings without inventive effort.

FIGS. 1 and 2 are process flow diagrams of a manufacturing method of an electromagnetic shielding structure provided in the embodiment of the present disclosure;

FIG. 3 is a schematic structural diagram of a shielding portion adopting a shielding pillar in a packaging structure provided in the embodiment of the present disclosure;

FIG. 4 is a schematic structural diagram of a projection of a shielding portion on a substrate in a packaging structure provided in the embodiment of the present disclosure;

FIG. 5 is a schematic structural diagram of a shielding portion adopting a shielding wall in a packaging structure provided in the embodiment of the present disclosure;

FIG. 6 is a schematic structural diagram of a projection of a shielding wall on a substrate in a packaging structure provided in the embodiment of the present disclosure;

FIG. 7 is a schematic structural diagram of one structure of a shielding portion in a packaging structure provided in the embodiment of the present disclosure;

FIGS. 8 and 9 are schematic structural diagrams of a projection of a shielding portion on a substrate having an opening shape in a packaging structure provided in the embodiment of the present disclosure;

FIGS. 10 to 14 are schematic structural diagrams of several structures of a shielding portion in a packaging structure provided in the embodiment of the present disclosure;

FIG. 15 is a schematic structural diagram of an alternately arranged structure of a shielding portion and a shielding wire in a packaging structure provided in the embodiment of the present disclosure;

FIG. 16 is a schematic structural diagram of a shielding portion being directly formed on a solder mask in a packaging structure provided in the embodiment of the present disclosure;

FIG. 17 is a schematic structural diagram of one structure of a shielding portion formed on a pad in a packaging structure provided in the embodiment of the present disclosure;

FIG. 18 is a schematic structural diagram of another structure of a shielding portion formed on a pad in a packaging structure provided in the embodiment of the present disclosure;

FIG. 19 is a schematic structural diagram of one structure of a shielding pillar being directly formed on a substrate without providing a pad in a packaging structure provided in the embodiment of the present disclosure;

FIG. 20 is a schematic structural diagram of one structure of a shielding portion adopting a hollow structure in a packaging structure provided in the embodiment of the present disclosure; and

FIG. 21 is a schematic structural diagram of one structure of a shielding portion adopting a hollow structure and being distributed on a sawing path in a packaging structure provided in the embodiment of the present disclosure.

Reference numerals: 100-packaging structure; 110-substrate; 111-wiring layer; 112-welding pad; 113-solder mask; 114-solder pad; 115-grounding wiring layer; 121-first element; 122-second element; 130-shielding portion; 131-shielding pillar; 132-shielding wall; 141-first end; 142-second end; 143-through hole; 144-groove; 145-main body portion; 150-encapsulation; 160-solder ball; 170-metal layer; 180-shielding wire.

### DETAILED DESCRIPTION OF EMBODIMENTS

In order to make the objectives, technical solutions, and advantages of the embodiments of the present disclosure clearer, the technical solutions in the embodiments of the present disclosure will be clearly and completely described below in conjunction with the drawings in the embodiments of the present disclosure. It is evident that the described embodiments are part of the embodiments of the present disclosure, but not all of the embodiments. The components of the embodiments of the present disclosure described and illustrated in the drawings can typically be arranged and designed in various configurations.

Therefore, the following detailed description of the embodiments of the present disclosure provided in the drawings is not intended to limit the scope of the present disclosure for which protection is claimed, but merely represents selected embodiments of the present disclosure. Based on the embodiments of the present disclosure, all other embodiments obtained by those skilled in the art without inventive effort shall fall within the scope of protection of the present disclosure.

It should be noted that similar numerals and letters denote similar terms in the following drawings so that once an item is defined in one drawing, it does not need to be further discussed in subsequent drawings.

In the description of the present disclosure, it should be noted that the terms “up”, “down”, “inner”, “outer”, and similar directional or positional terms are based on the orientation or positional relationship shown in the drawings, or they represent the customary orientation or positional relationship when the disclosed product is used. These terms are used solely for describing the present disclosure and simplifying the description, and do not indicate or imply that the device or component referred to must have a specific orientation, be constructed and operated in a particular orientation. Therefore, they should not be understood as limiting the scope of the present disclosure.

In addition, terms such as “first”, and “second”, are only used to distinguish the descriptive and are not to be construed as indicating or implying relative importance.

It should be noted that the features in the embodiments of the present disclosure can be combined with each other without conflict.

The objectives of the present disclosure include, for example, providing a manufacturing method of an electromagnetic shielding structure and a packaging structure, which can improve wire bonding efficiency and wire bonding quality and enhance electromagnetic shielding reliability.

The embodiments of the present disclosure can be implemented as follows.

In a first aspect, the present disclosure provides a manufacturing method of an electromagnetic shielding structure, including
providing a substrate having a first element;
forming a shielding portion on the substrate by using 3D printing technology, wherein the shielding portion is arranged at a periphery of the first element; and the step comprises: constructing a three-dimensional model of the shielding portion; identifying a target position on the substrate; and laying printing material at the target position in accordance with the three-dimensional model to pre-form the shielding portion;
injecting a molding compound onto the substrate to form an encapsulation that encapsulates the first element and the shielding portion, wherein the molding compound undergoes a crosslinking reaction with the printing material;
grinding the encapsulation so that the shielding portion is exposed from a surface of the encapsulation; and
forming a metal layer on the surface of the encapsulation, wherein the metal layer is electrically connected to the shielding portion, and at least one of the metal layer and the shielding portion has grounding properties.

In one or more embodiments, in the step of laying printing material at the target position in accordance with the three-dimensional model to pre-form the shielding portion, the pre-forming temperature is 100° C. to 200° C.

In the step of injecting a molding compound onto the substrate to form an encapsulation that encapsulates the first element and the shielding portion, the curing temperature of the molding compound is 250° C. to 350° C.

In one or more embodiments, the printing material is nano-metal conductive paste.

In one or more embodiments, a solder mask is arranged on the surface of the substrate; and in the step of forming the shielding portion on the substrate by using 3D printing technology, the shielding portion is directly formed on the solder mask.

In one or more embodiments, a solder mask is arranged on the surface of the substrate; the substrate is provided with a solder pad exposed from the surface of the solder mask;
and in the step of forming the shielding portion on the substrate by using 3D printing technology, the shielding portion is directly formed on the solder pad.

In one or more embodiments, the shielding portion has a first end and a second end that are oppositely arranged, wherein the first end is connected to the substrate, a sectional area of the second end is smaller than a sectional area of the first end, and the second end has a tip.

In one or more embodiments, the second end is continuously bent in a Z shape, wavy shape, or stepped shape.

In one or more embodiments, the section of the second end is arc-shaped, sector-shaped, or polygonal, and the section of the second end gradually decreases in a direction away from the substrate.

In one or more embodiments, the second end is provided with a through hole and/or a groove.

In one or more embodiments, the step of forming the shielding portion on the substrate by using 3D printing technology includes:
forming a main body portion having a first end on the substrate by using 3D printing technology; and
forming the second end at an end of the main body portion away from the first end by using 3D printing technology, wherein the through hole and/or the groove is integrally formed in the step of forming the second end by using 3D printing.

In one or more embodiments, the shielding portion includes multiple shielding pillars arranged at intervals; and/or, the shielding portion includes a shielding wall having a continuous surface.

In one or more embodiments, the projection shape of the shielding portion on the substrate is a closed shape or has at least one opening.

In one or more embodiments, a second element is further arranged on the substrate, and the shielding portion isolates the first element from the second element.

In one or more embodiments, the shielding portion is arranged at the periphery of the first element, and a shielding wire formed by wire bonding is arranged at the periphery of the second element.

A second aspect of the present disclosure further provides a packaging structure, wherein the packaging structure is prepared using the manufacturing method of the electromagnetic shielding structure as described in the first aspect. In one or more embodiments, a shielding structure is arranged at the periphery of the first element, and the shielding structure entirely uses the shielding portion formed by 3D printing;
or, the shielding structure includes the shielding portion formed by 3D printing and the shielding wire formed by wire bonding, wherein the shielding portion formed by 3D printing and the shielding wire formed by wire bonding are alternately arranged or arranged side by side.

The beneficial effects of the embodiments of the present disclosure include the following.

For example, the manufacturing method of the electromagnetic shielding structure and the packaging structure provided in the embodiments of the present disclosure utilize 3D printing technology to form the shielding portion configured for shielding and isolating the first element. The shielding portion can be pre-formed first, and during encapsulation, the molding compound undergoes a crosslinking reaction with the printing material of the shielding portion, which can further secure and reinforce the shielding portion, preventing the shielding portion from tilting or deforming. Moreover, this improves the bonding strength between the shielding portion and the encapsulation, thereby enhancing electromagnetic shielding reliability.

The technical solutions of the embodiments of the present disclosure will be further described in detail below with reference to the drawings.

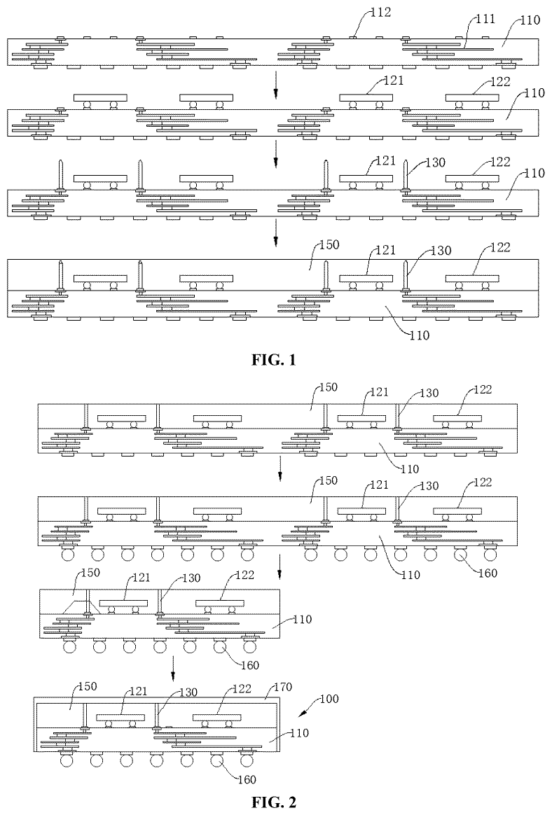

Referring to FIGS. 1 and 2, the embodiments provide a manufacturing method of an electromagnetic shielding structure, which mainly includes the following steps.
Step S1: providing a substrate 110 having a first element 121.
Step S2: forming a shielding portion 130 on the substrate 110 by using 3D printing technology, wherein the shielding portion 130 is arranged at a periphery of the first element 121. The step includes: constructing a three-dimensional model of the shielding portion 130; identifying a target position on the substrate 110; and laying printing material at the target position in accordance with the three-dimensional model to pre-form the shielding portion 130.
Step S3: injecting a molding compound onto the substrate 110 to form an encapsulation 150 that encapsulates the first element 121 and the shielding portion 130, wherein the molding compound undergoes a crosslinking reaction with the printing material.
Step S4: grinding the encapsulation 150 so that the shielding portion 130 is exposed from a surface of the encapsulation 150.
Step S5: forming a metal layer 170 on the surface of the encapsulation 150, wherein the metal layer is electrically connected to the shielding portion 130, and at least one of the metal layers 170 and the shielding portion 130 has grounding properties.

In the embodiments, a 3D printing technology is utilized to form the shielding portion 130 configured for shielding and isolating the first element 121. The shielding portion 130 can be pre-formed first, and during encapsulation, the molding compound undergoes a crosslinking reaction with the printing material of the shielding portion 130, which can further secure and reinforce the shielding portion 130, preventing the shielding portion 130 from tilting or deforming. Moreover, this improves the bonding strength between the shielding portion 130 and the encapsulation 150, thereby enhancing electromagnetic shielding reliability.

In step S1, a substrate 110 is provided, and a wiring layer 111 is embedded in the substrate 110 in advance. The wiring layer 111 extends to the surface of the substrate 110 to form a welding pad 112. A first element 121 is mounted on the welding pad 112 of the substrate 110 to achieve an electrical connection between the first element 121 and the substrate 110. The first element 121 includes but is not limited to a chip or a component. One or multiple first elements 121 can be provided.

Optionally, a second element 122 can also be mounted on the substrate 110 and arranged at intervals with the first element 121. The second element 122 is electrically connected to the substrate 110. One or multiple second elements 122 can be provided. The second element 122 includes but is not limited to a chip or a component. A shielding portion 130 is configured to isolate the first element 121 from the second element 122 to prevent mutual interference between the first element 121 and the second element 122.

In step S2, based on a pre-constructed three-dimensional model of the shielding portion 130, a pre-formed shielding portion 130 is formed on the substrate 110 by 3D printing. Optionally, the printing material of the shielding portion 130 is selected as a nano-metal conductive paste. The nano-metal conductive paste can be a composition formed of nano-metals, epoxy resin, polyurethane resin, nano-graphene powder, and polymer materials. The nano-metals include but are not limited to at least one of nano-gold, nano-silver, and nano-copper. The printing material is a thermosetting material. The pre-forming temperature is 100° C. to 200°°C. , which facilitates the pre-curing and shaping of the shielding portion 130. Optionally, the printing time of each shielding portion 130 is determined based on the printing material and printing area, and is approximately 30 seconds to 2 minutes.

In step S3, an encapsulation 150 is formed using a molding encapsulation process. During encapsulation, the encapsulation process and baking temperature induce a crosslinking reaction between the molding compound and the printing material, thereby fully curing the nano-metal conductive paste and enhancing the bonding strength between the encapsulation 150 and the conductive paste. Optionally, the encapsulation process and baking curing temperature of the molding compound is 250° C. to 350° C.

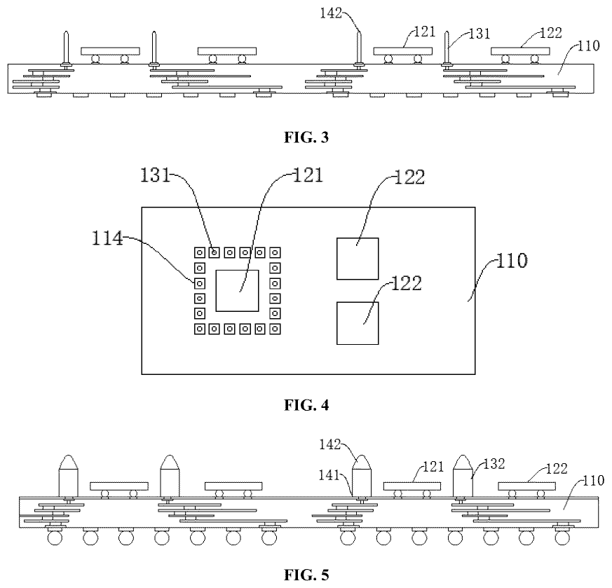

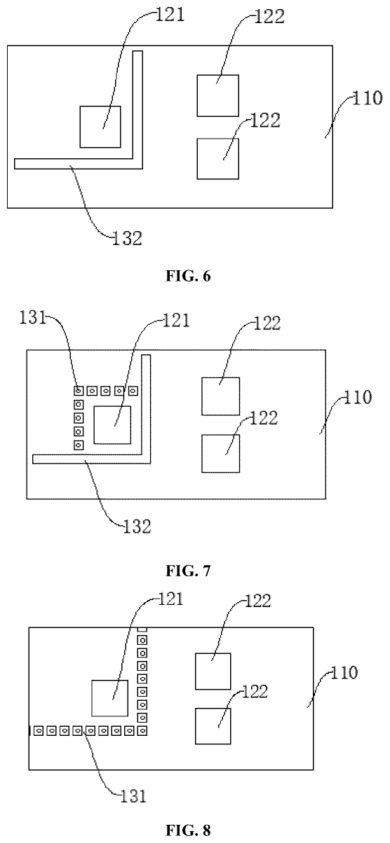

Referring to FIG. 3 and FIG. 4, optionally, the shielding portion 130 includes multiple shielding pillars 131 arranged at intervals. Alternatively, referring to FIG. 5 and FIG. 6, the shielding portion 130 includes a shielding wall 132 having a continuous surface. The shielding wall 132 can adopt a solid or hollow structure. Alternatively, referring to FIG. 7, the shielding portion 130 can simultaneously include a shielding pillar 131 and a shielding wall 132. For example, one or several sides can use shielding pillars 131 for isolation shielding, and the remaining sides use shielding walls 132 for shielding isolation.

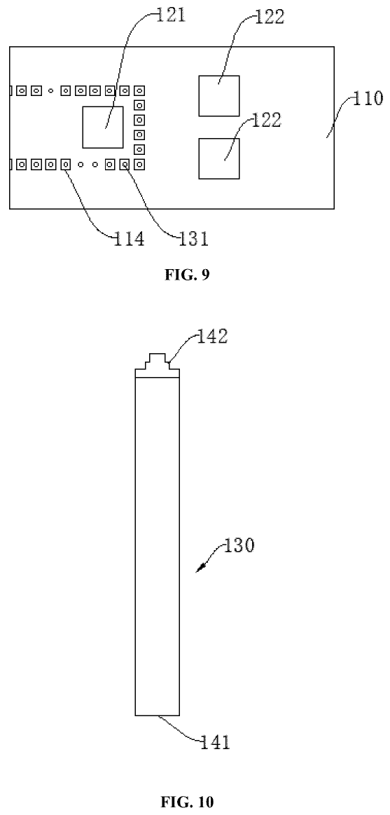

Optionally, the projection shape of the shielding portion 130 on the substrate 110 is a closed shape or has at least one opening. Referring to FIG. 4, if the projection is a closed shape, it can be circular, elliptical, square, rectangular, triangular, rhombic, pentagonal, hexagonal, or other polygons. Referring to FIG. 6, FIG. 8, and FIG. 9, the projection shape with an opening includes but is not limited to a linear shape, L-shape, cross shape, C-shape, U-shape, T-shape, X-shape, H-shape, Z-shape, or N-shape, which is not specifically limited herein.

It can be understood that the shielding portion 130 can adopt the shielding pillar 131 or the shielding wall 132 as the structural form. Referring to FIG. 5, the shielding portion 130 has a first end 141 and a second end 142 disposed oppositely. The first end 141 is connected to the substrate 110, and the second end 142 is relatively farther from the substrate 110. The sectional area of the second end 142 is smaller than the sectional area of the first end 141. That is, the second end 142 forms an opposing tapered portion. With this arrangement, during encapsulation, the tapered portion serves as a flow diverter for the encapsulation mold flow, accelerating the flow movement while reducing the pressure of the mold flow on the top of the shielding portion 130. This prevents the shielding portion 130 from bending, tilting, breaking, or other deformations caused by mold flow pressure. Additionally, the tapered portion increases the contact area between the shielding portion 130 and the encapsulation 150, fully utilizing the crosslinking reaction to enhance the bonding force between them and improve structural reliability.

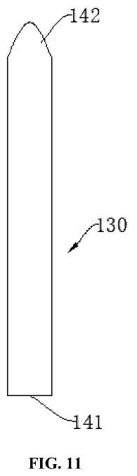

Optionally, as shown in FIG. 10, the second end 142 can be of a stepped shape, with the number of steps being two, three, four, or more. As shown in FIG. 11, it can also be conical or frustoconical, meaning the surface tapers smoothly.

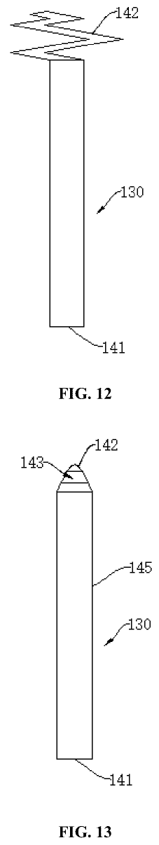

Alternatively, as shown in FIG. 12, the second end 142 is continuously bent in a Z shape, wavy shape, or stepped shape. With this arrangement, since the second end 142 has multiple bends, it changes the stress state and stress points of the second end 142, helping to mitigate the impact of mold flow and reduce the risk of deformation of the shielding portion 130 caused by molding pressure.

Optionally, the section of the second end 142 gradually decreases in the direction away from the substrate 110. It can be understood that the second end 142 can be spherical, hemispherical, ellipsoidal, prismatic, pyramidal, or any other shape. The section of the second end 142 can be arc-shaped, fan-shaped, triangular, or a combination of polygons or multiple shapes.

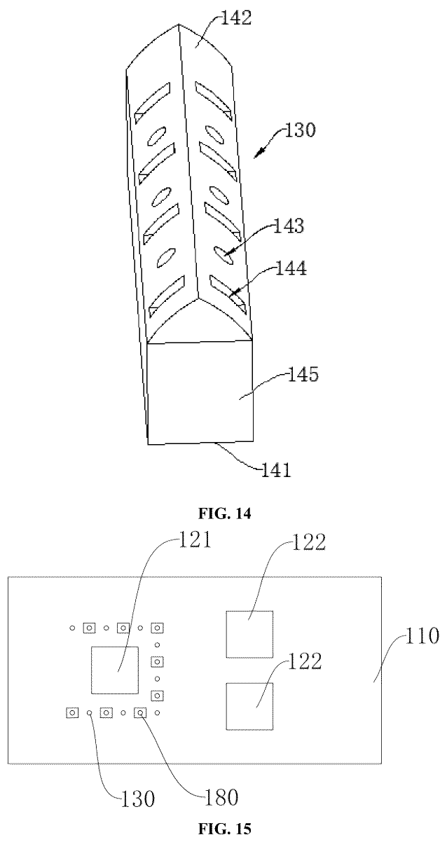

Optionally, as shown in FIG. 13 and FIG. 14, the second end 142 is provided with a through hole 143 and/or a groove 144. It can be understood that the second end 142 can be provided with a through hole 143, a groove 144, or both a through hole 143 and a groove 144, which is not specifically limited here.

It can be understood that, in the step of forming the shielding portion 130 on the substrate 110 by using 3D printing technology, a main body portion 145 having a first end 141 can first be formed on the substrate 110 using 3D printing technology. The main body portion 145 extends perpendicularly to the substrate 110 and in a direction away from the substrate 110. Then, the second end 142 is formed at the end of the main body portion 145 away from the first end 141 using 3D printing technology, wherein the through hole 143 and/or the groove 144 is integrally molded in the step of forming the second end 142 by using 3D printing. Of course, it is not limited to this and can also be formed after the second end 142 is formed by 3D printing, using laser, etching, electron beam, or other methods to form the through hole 143 or the groove 144 on the second end 142. Referring to FIG. 13, a structure of a through hole 143 is formed on the shielding pillar 131. Referring to FIG. 14, a structure of a through hole 143 and a groove 144 is formed on the shielding wall 132.

In some embodiments, referring to FIG. 15, the structure for shielding and isolating the first element 121 can include both the shielding portion 130 formed using 3D printing and the shielding wire 180 formed using vertical wire bonding. The shielding portion 130 formed using 3D printing and the shielding wire 180 formed using wire bonding can be alternately arranged or arranged side by side. Alternate arrangement can be understood as being in the same direction, such as on one side or the periphery of the first element 121, with an alternating layout of “the shielding portion 130 formed using 3D printing, the shielding wire 180 formed using wire bonding, the shielding portion 130 formed using 3D printing, the shielding wire 180 formed using wire bonding . . . ”. Alternatively, around the first element 121, at least one side is entirely formed by the shielding portion 130 using 3D printing, and the adjacent or opposite side is entirely formed by the shielding wire 180 using wire bonding. The side-by-side arrangement can be understood as having multiple layers of shielding structures around the first element 121, such as inner shielding layers and outer shielding layers. Among the inner shielding layers and outer shielding layers, one is entirely formed by the shielding portion 130 using 3D printing, and the other is entirely formed by the shielding wire 180 using wire bonding.

Alternatively, in some embodiments, both the first element 121 and the second element 122 require shielding isolation. The formed shielding structure surrounding the first element 121 is the shielding portion 130 formed by using 3D printing, and the formed shielding structure surrounding the second element 122 is the shielding wire 180 formed by using wire bonding. Alternatively, the shielding structures surrounding both the first element 121 and the second element 122 include both the shielding portion 130 formed using 3D printing and the shielding wire 180 formed using wire bonding, which is not specifically limited herein.

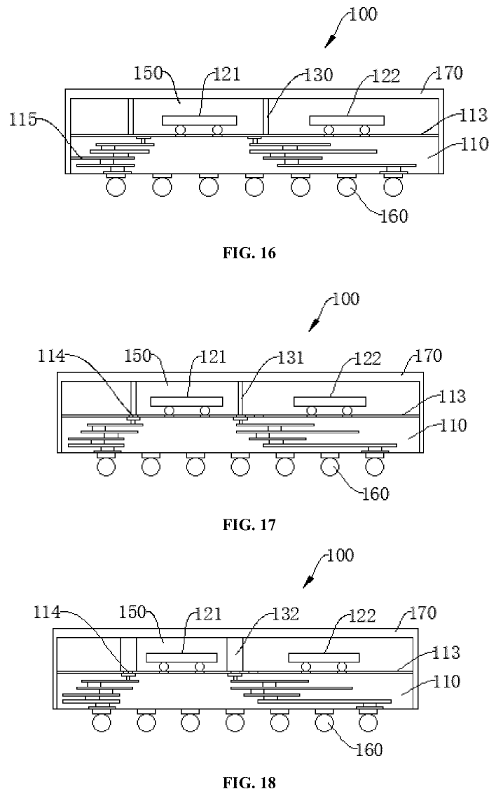

Optionally, in combination with FIG. 16, a solder mask 113 is arranged on the surface of the substrate 110; and in the step of forming the shielding portion 130 on the substrate 110 by using 3D printing technology, the shielding portion 130 is directly formed on the solder mask 113. In this way, there is no need to form solder pads 114 on the substrate 110, significantly reducing the design of the grounding wiring layer 115 and reducing the number and length of wiring layers 111 in the substrate 110. Therefore, the parasitic effect and electromagnetic interference caused by the wiring layer 111 can be substantially reduced.

In some embodiments, in combination with FIGS. 17 and 18, a solder mask 113 is arranged on the surface of the substrate 110; the substrate 110 is provided with a solder pad 114 exposed from the surface of the solder mask 113; and in the step of forming the shielding portion 130 on the substrate 110 by using 3D printing technology, the shielding portion 130 is directly formed on the solder pad 114. In FIG. 17, the shielding pillar 131 is formed on the solder pad 114. In FIG. 18, the shielding wall 132 is formed on the solder pad 114.

The arrangement of the solder pad 114 facilitates positioning the printing target position during 3D printing and enhances the bonding strength between the substrate 110 and the shielding portion 130. The solder pad 114 can be formed by extending the grounding wiring layer 115 inside the substrate 110 to the surface. That is to say, the solder pad 114 and the wiring layer 111 are electrically connected. Alternatively, the solder pad 114 can be directly formed on the solder mask 113 as a seed layer for forming the shielding portion 130, in which case the solder pad 114 and the grounding wiring layer 115 cannot have an electrical connection.

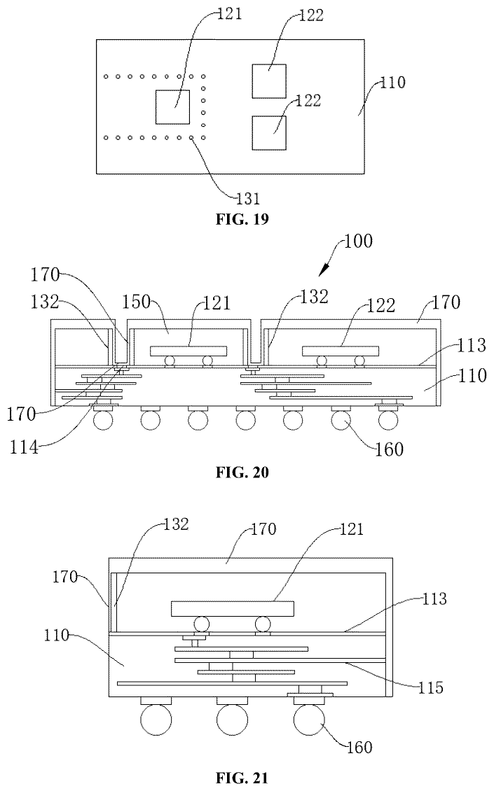

Optionally, the solder pad 114 has grounding properties. The quantity and shape of the solder pads 114 can be flexibly designed and are not specifically limited. If the shielding portion 130 adopts the structure of shielding pillars 131, one shielding pillar 131 is printed on each solder pad 114. The number of solder pads 114 is equal to the number of shielding pillars 131, as shown in FIG. 4. In some embodiments, the number of solder pads 114 can be less than the number of shielding pillars 131. That is, some shielding pillars 131 do not provide the solder pads 114 underneath, and only some shielding pillars 131 provide the solder pads 114 underneath, as shown in FIG. 9. This design can reduce the number of solder pads 114, thereby decreasing the number and length of wiring layers 111 and further reducing parasitic effect and electromagnetic interference. Alternatively, all shielding pillars 131 can be directly printed on the solder mask 113 of the substrate 110 without the arrangement of the solder pads 114, as shown in FIG. 19.

In some embodiments, the surface area of the solder pad 114 can be larger than the total sectional area of multiple shielding pillars 131, meaning the solder pad 114 is designed with a larger area and is distributed in a planar manner. Multiple shielding pillars 131 can be printed on a solder pad 114. If the shielding portion 130 adopts the structure of shielding walls 132, the bottom area of the shielding wall 132 can be equal to and similar in shape to the solder pad 114. Alternatively, in some embodiments, the area of the solder pad 114 can be smaller than the bottom area of the shielding wall 132, with part of the bottom of the shielding wall 132 positioned on the solder pad 114 and part on the solder mask 113, which is not specifically limited.

Additionally, the solder pads 114 can be distributed in a spotty manner, a planar manner, or a combination of both. The solder pad 114 can extend to the sawing path region, that is, the solder pads 114 are sawed and exposed from the side edge when sawed and separated. Of course, the solder pad 114 can also be designed to avoid the sawing path, which is not specifically limited herein.

It is worth noting that in traditional metal wire bonding, the surface of the substrate must be designed with wire-bonding pads so that the shielding wire 180 can be bonded onto the wire-bonding pads. This is because traditional wire bonding cannot be achieved on non-metallic materials such as the solder mask. However, in the embodiment, 3D printing technology is employed, which allows the shielding portion 130 to be directly formed on the solder mask 113 without the arrangement of the solder pads 114, simplifies the process, improves process efficiency, and makes the structural design of the substrate 110 more flexible.
Step S4: grinding, after the encapsulation 150 is cured, the encapsulation 150 so that the shielding portion 130 is exposed from a surface of the encapsulation 150. In the grinding process, the portion of the encapsulation 150 that protrudes beyond the shielding portion 130 needs to be completely polished. Alternatively, the encapsulation 150 and part of the shielding portion 130 can be ground together to achieve a smoother surface. The grinding thickness is determined based on actual conditions, and the second end 142 can be partially removed or entirely removed by grinding, which is not specifically limited.

In the embodiment, the second end 142 is completely removed by grinding so that the larger section of the shielding portion 130 is in contact with the subsequently sputtered metal layer 170. This increases the contact area and enhances contact reliability. Furthermore, configuring the second end 142 as a pointed tip with a gradually reduced sectional area helps to decrease the likelihood of adjacent shielding pillars 131 touching during grinding. This prevents cracks or fractures in the shielding portion 130 during the grinding process, reduces the volume of the shielding portion 130 that needs to be ground, and improves grinding efficiency.

After grinding, the solder balls 160 are planted on the side of the substrate 110 opposite the encapsulation 150. Finally, individual products are formed by sawing along the sawing path.
Step S5: protecting the solder balls 160 at the bottom, performing sputtering on the individual product, and respectively forming a metal layer 170 on the upper surface and four side surfaces of the encapsulation 150, wherein the metal layer 170 is in contact with the shielding portion 130 exposed on the surface of the encapsulation 150 to achieve electrical connection, thereby completing the preparation of the shielding structure.

Referring to FIG. 20, if the shielding wall 132 is of a hollow structure, after the second end 142 is removed by grinding, the cavity of the shielding wall 132 is exposed. During the subsequent sputtering process of the metal layer 170, the metal layer 170 adheres to the inner wall of the cavity and the surface of the substrate 110. Optionally, the metal layer 170 attached to the surface of the substrate 110 is in contact with the solder pad 114. This enables a dual-layer shielding structure, providing more reliable shielding performance.

Referring to FIG. 21, in some embodiments, the hollow shielding wall 132 can also be arranged on the sawing path. After the subsequent sawing process, the remaining inner wall on one side serves as an electromagnetic shielding partition. If the first element 121 is symmetrically arranged relative to the sawing path during the mounting of the first element 121, and the hollow shielding wall 132 is located on the sawing path, then after sawing and separation, a single shielding wall 132 is split into two halves. Each half is applied to a separate unit: one half serving as shielding for one first element 121, and the other half serving as shielding for another first element 121. This significantly improves packaging efficiency.

Of course, in some embodiments, the hollow shielding wall 132 can be arranged to avoid the sawing path, which is not specifically limited. It should be understood that similarly, if the shielding portion 130 adopts the structure of shielding pillars 131, it can also adopt a hollow or solid structure and can be arranged on the sawing path or designed to avoid the sawing path, which is not specifically limited.

It should be noted that if no solder pad 114 is arranged on the solder mask 113, or if a solder pad 114 is arranged but is not electrically connected to the grounding wiring layer 115 inside the substrate 110, the grounding wiring layer 115 in the substrate 110 can be extended to the sawing path. After sawing, the wiring layer 111 is exposed from the sawed side wall, as shown in FIG. 15. Then, metal sputtering is performed to form the metal layer 170. This allows the metal layer 170 to contact the grounding wiring layer 115 exposed from the side wall, thus having grounding properties and achieving electromagnetic shielding effects. Of course, other methods can also be used to ground the shielding portion 130 or the metal layer 170 to achieve electromagnetic shielding.

The embodiments of the present disclosure further provide a packaging structure 100, which is prepared by adopting the manufacturing method of the electromagnetic shielding structure. In the packaging structure 100, the shielding portion 130 configured for isolating the first element 121 from the second element 122 is formed using 3D printing technology, which improves the efficiency and quality of wire bonding. The printing material is a conductive paste, which can undergo a crosslinking reaction with the molding compound, thereby enhancing structural strength and bonding force to improve packaging reliability. Furthermore, the shielding portion 130 can adopt structures such as shielding pillars 131 or shielding walls 132, thus providing greater structural flexibility. The second end 142 of the shielding portion 130 can be configured with one or more of the following structural features: a pointed tip, a step portion, a Z-shaped bending portion, a groove 144, or a through hole 143, which effectively alleviates molding stress, reduces the risk of deformation of the shielding portion 130, ensures uniform spacing when the shielding portion 130 adopts the shielding pillar 131 structure, provides reliable electromagnetic shielding performance, and prevents noise interference.

In summary, the manufacturing method of the electromagnetic shielding structure and the packaging structure 100 provided by the embodiments of the present disclosure have beneficial effects in several aspects, including the following.

For example, the manufacturing method of the electromagnetic shielding structure and the packaging structure 100 provided in the embodiments of the present disclosure utilize 3D printing technology to form the shielding portion 130 configured for shielding and isolating the first element 121. The shielding portion 130 can be pre-formed first, and during encapsulation, the molding compound undergoes a crosslinking reaction with the printing material of the shielding portion 130, which can further secure and reinforce the shielding portion 130, preventing the shielding portion 130 from tilting or deforming. Moreover, this improves the bonding strength between the shielding portion 130 and the encapsulation 150, thereby enhancing electromagnetic shielding reliability.

The above are just specific embodiments of the present disclosure, but the scope of protection of the present disclosure is not limited to the embodiments. Any variations or substitutions, readily apparent to those skilled in the art within the technical scope disclosed in the present disclosure, should be encompassed within the scope of protection of the present disclosure. Therefore, the scope of protection of the present disclosure shall be stated to be subject to the scope of protection of the claims.

### INDUSTRIAL PRACTICALITY

The manufacturing method of the electromagnetic shielding structure and the packaging structure provided in the embodiments of the present disclosure utilize 3D printing technology to form the shielding portion configured for shielding and isolating the first element. The shielding portion can be pre-formed first, and during encapsulation, the molding compound undergoes a crosslinking reaction with the printing material of the shielding portion, which can further secure and reinforce the shielding portion, preventing the shielding portion from tilting or deforming. Moreover, this improves the bonding strength between the shielding portion and the encapsulation, thereby enhancing electromagnetic shielding reliability.

1. A manufacturing method of an electromagnetic shielding structure, comprising:
providing a substrate having a first element;
forming a shielding portion on the substrate by using 3D printing technology, wherein the shielding portion is arranged at a periphery of the first element; and the step comprises: constructing a three-dimensional model of the shielding portion; identifying a target position on the substrate; and laying a printing material at the target position in accordance with the three-dimensional model to pre-form the shielding portion;
injecting a molding compound onto the substrate to form an encapsulation that encapsulates the first element and the shielding portion, wherein the molding compound undergoes a crosslinking reaction with the printing material;
grinding the encapsulation so that the shielding portion is exposed from a surface of the encapsulation; and
forming a metal layer on the surface of the encapsulation, wherein the metal layer is electrically connected to the shielding portion, and at least one of the metal layer and the shielding portion has grounding properties.

2. The manufacturing method of an electromagnetic shielding structure according to claim 1, wherein in the step of laying printing material at the target position in accordance with the three-dimensional model to pre-form the shielding portion, a pre-forming temperature is 100°C. to 200°C.; and
in the step of injecting a molding compound onto the substrate to form an encapsulation that encapsulates the first element and the shielding portion, a curing temperature of the molding compound is 250°C. to 350°C.

3. The manufacturing method of an electromagnetic shielding structure according to claim 1, wherein the printing material is nano-metal conductive paste.

4. The manufacturing method of an electromagnetic shielding structure according to claim 1, wherein a solder mask is arranged on the surface of the substrate; and in the step of forming a shielding portion on the substrate by using 3D printing technology, the shielding portion is directly formed on the solder mask.

5. The manufacturing method of an electromagnetic shielding structure according to claim 1, wherein a solder mask is arranged on the surface of the substrate; the substrate is provided with a solder pad exposed from a surface of the solder mask; and
in the step of forming a shielding portion on the substrate by using 3D printing technology, the shielding portion is directly formed on the solder pad.

6. The manufacturing method of an electromagnetic shielding structure according to claim 1, wherein the shielding portion is provided with a first end and a second end that are oppositely arranged, the first end is connected to the substrate, a sectional area of the second end is smaller than a sectional area of the first end, and the second end has a tip.

7. The manufacturing method of an electromagnetic shielding structure according to claim 6, wherein the second end is continuously bent in a Z shape, wavy shape, or stepped shape.

8. The manufacturing method of an electromagnetic shielding structure according to claim 6, wherein a section of the second end is arc-shaped, sector-shaped, or polygonal, and the section of the second end gradually decreases in a direction away from the substrate.

9. The manufacturing method of an electromagnetic shielding structure according to claim 6, wherein the second end is provided with a through hole and/or a groove.

10. The manufacturing method of an electromagnetic shielding structure according to claim 9, wherein the step of forming a shielding portion on the substrate by using 3D printing technology comprises:
forming a main body portion having the first end on the substrate by using the 3D printing technology; and
forming the second end at an end of the main body portion away from the first end by using the 3D printing technology, wherein the through hole and/or the groove is integrally formed in the step of forming the second end by using 3D printing.

11. The manufacturing method of an electromagnetic shielding structure according to claim 6, wherein the shielding portion comprises multiple shielding pillars arranged at intervals; and/or, the shielding portion comprises a shielding wall having a continuous surface.

12. The manufacturing method of an electromagnetic shielding structure according to claim 1, wherein a projection shape of the shielding portion on the substrate is a closed shape or has at least one opening.

13. The manufacturing method of an electromagnetic shielding structure according to claim 1, wherein a second element is further arranged on the substrate, and the shielding portion isolates the first element from the second element.

14. The manufacturing method of an electromagnetic shielding structure according to claim 13, wherein the shielding portion is arranged at the periphery of the first element, and a shielding wire formed by wire bonding is arranged at a periphery of the second element.

15. A packaging structure, prepared using the manufacturing method of an electromagnetic shielding structure according to claim 1.

16. The packaging structure according to claim 15, wherein the shielding structure is arranged at the periphery of the first element, and the shielding structure entirely uses the shielding portion formed by 3D printing; or,
the shielding structure comprises the shielding portion formed by 3D printing and a shielding wire formed by wire bonding, wherein the shielding portion formed by 3D printing and the shielding wire formed by wire bonding are alternately arranged or arranged side by side.
